(19) United States
(12) Patent Application Publication
(10) Pub. No.: US 2010/0271018 A1
(43) Pub. Date: Oct. 28, 2010

(54) SENSORS FOR MINUTE MAGNETIC FIELDS

(75) Inventor: Thomas William Clinton, Pittsburgh, PA (US)

Correspondence Address: PIETRAGALLO GORDON ALFANO BOSICK & RASPANTI, LLP, ONE OXFORD CENTRE, 38TH FLOOR, 301 GRANT STREET, PITTSBURGH, PA, 15219-6404, US

(73) Assignee: SEAGATE TECHNOLOGY LLC, Scotts Valley, CA (US)

(21) Appl. No.: 12/429,220

(22) Filed: Apr. 24, 2009

(51) Int. Cl. G01R 33/02; G01R 33/09; G01R 33/07

(52) U.S. Cl. 324/252; 324/244; 324/251

(57) ABSTRACT

A magnetic sensor includes a flux concentrator and a transducer producing an output responsive to a change in magnetization in the flux concentrator. The flux concentrator can include first, second and third portions, wherein the third portion is between the first and second portions and the cross-sectional area of the third portion is smaller than the cross-sectional area of the first and second portions, and the transducer can produce an output responsive to a change in magnetization in the third portion of the flux concentrator.

### BACKGROUND

Detection of minute magnetic fields has relevance to a range of applications from military to medical, while the magnetic field sources are as varied as magnetic anomalies of moving vehicles to neural activity. These applications have driven field-detection technology to sensitivities approaching 10⁻¹⁶ Tesla/√Hz. This requires superconducting quantum interference device (SQUID) sensors or flux-collecting superconducting elements integrated with other traditional field sensors, either of which requires low-temperature operation. The cryogenic requirements create significant limitations such as higher power consumption, exhaustible refrigerants, a bulky payload and large footprint, all of which can impede military applications where transportability is at a premium. Devices operating at room temperature run out of sensitivity near 10⁻¹¹ Tesla/√Hz, as output signals fall below the noise floor, often characterized by 1/f-like behavior associated with various forms of electronic, magnetic and thermal noise, where f is the frequency of the magnetic field being sensed by the sensor.

Flux concentrators have been proposed by others to amplify magnetic field, and the amplified field is applied to a transducer, which can be positioned in a gap in the flux concentrator. The boosted field effects a change in magnetization, which is converted to an output voltage via a magneto-electric effect, such as magnetoresistance or magnetostriction-induced voltage in a coupled piezoelectric layer. However, the gap in such flux concentrators results in demagnetizing fields that limit the field amplification to an order of magnitude, or less.

### SUMMARY

In a first aspect, the invention provides a magnetic sensor including a flux concentrator and a transducer producing an output responsive to a change in magnetization in the flux concentrator.

In another aspect, the invention provides a magnetic sensor including a flux concentrator having first and second portions and a third portion between the first and second portions, wherein the cross-sectional area of the third portion is smaller than the cross-sectional area of the first and second portions, and wherein the third portion of the flux concentrator includes an Extraordinary Hall Effect material.

### BRIEF DESCRIPTION OF THE DRAWINGS

FIG. 1 is a cross-sectional view of an embodiment of a sensor constructed in accordance with an aspect of the invention.

FIG. 2 is a cross-sectional view the sensor of FIG. 1 taken along line 2-2.

FIG. 3 is a graph of magnetization versus applied magnetic field.

FIG. 4 is a cross-sectional view of another embodiment of a sensor constructed in accordance with an aspect of the invention.

FIG. 5 is a cross-sectional view of the sensor of FIG. 4 taken along line 5-5.

FIG. 6 is a graph of voltage versus applied magnetic field.

FIG. 7 is a cross-sectional view of another embodiment of a sensor constructed in accordance with an aspect of the invention.

FIG. 8 is a cross-sectional view of the sensor of FIG. 7 taken along line 8-8.

FIG. 9 is a schematic representation of a sensor model used to simulate the operation of the sensor.

FIG. 10 is a graph of saturation field versus input to center area.

FIG. 11 is a schematic representation of another sensor in accordance with another aspect of the invention.

FIGS. 12 and 13 are schematic representations of a portion of the sensor of FIG. 11.

FIG. 14 is a schematic representation of the sensor of FIG. 11 with flux diverted to the flux concentrator.

FIGS. 15, 16 and 17 are schematic representations of additional examples of transducers in combination with a flux concentrator.

### DETAILED DESCRIPTION OF THE INVENTION

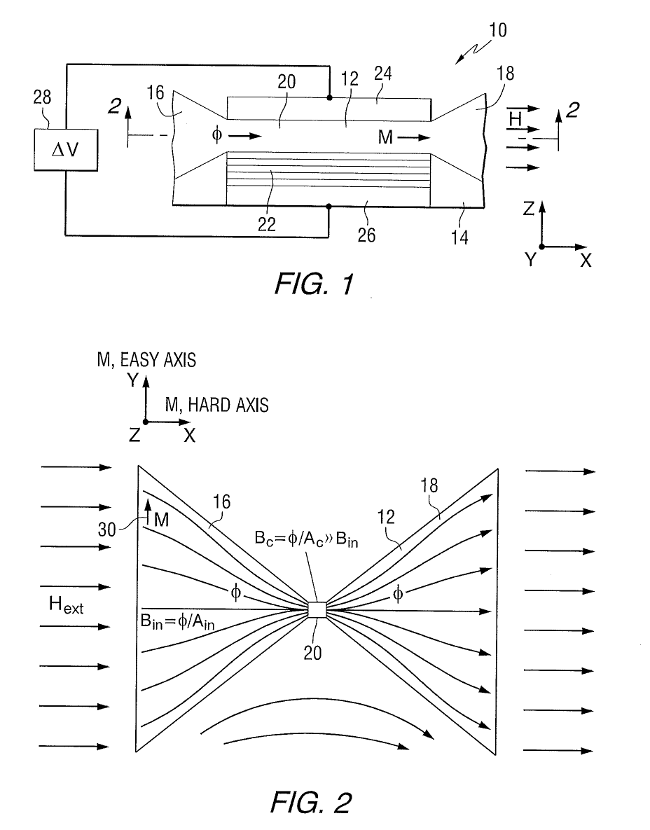

FIG. 1 is a schematic side elevation view of a portion of a sensor 10 constructed in accordance with an embodiment of the invention. The sensor includes a flux concentrator 12 of ferromagnetic magnetic material supported by a substrate 14 or other support structure. The flux concentrator includes first, second and third portions 16, 18 and 20. The first and second portions (also referred to as end portions) of the flux concentrator have a larger cross-sectional area than the third portion (also referred to as the center portion). In the embodiment of FIG. 1, the flux concentrator has a bow tie shape.

The flux concentrator can be a continuous ferromagnetic layer of high magnetic permeability that concentrates magnetic flux using a bow tie or hour glass like geometry. As used in this description, high magnetic permeability means a magnetic permeability of at least 100. The flux concentrator can be constructed of, for example, alloys of NiFe or CoFe, or magnetostrictive materials such as Terfenol-D (Tb₁₋ₓDy_{yx}Fe_{2-y}) or Galfenol (Fe₁₋ₓGaₓ).

When the sensor is exposed to a magnetic field H (e.g., applied in the X direction), magnetic flux φ passes through the flux concentrator, and induces a change in magnetization M in the flux concentrator. Because the end portions have a larger cross-sectional area than the center portion, the net magnetization of the center portion is larger than that of the end portions.

A transducer 22 is connected to the third portion of the flux concentrator. The transducer can be one of several devices that can be used to produce an output signal in response to a change in the magnetization of the center portion of the flux concentrator. For example, the transducer can produce an output voltage using a variety of known magneto-electric effects such as giant magnetoresistance (GMR), tunneling magnetoresistance (TMR), and multiferroic coupling, among others. As shown in FIG. 1, the transducer can include a plurality of layers that are coupled to the center portion of the flux concentrator. In some embodiments, the center portion of the flux concentrator can form a free layer in the transducer and the transducer can further include one or more pinned layers and one or more spacer layers that are structured and arranged to utilize the GMR or TMR effects to produce an output voltage.

Alternatively, the transducer can be used to produce an output in response to a physical change in the center portion resulting from the change in magnetization, for example a piezoelectric transducer that is connected to the center portion can respond to changes in the dimensions of the center portion caused by magnetostriction.

Electrodes 24 and 26 are provided to connect the sensor to an external circuit 28, which in one example can supply a bias current to the transducer and can measure a voltage between the electrodes.

The flux concentrator is formed of a high-permeability magnetic film with in-plane anisotropy and is designed to have a large cross-sectional area at both of its ends. The ends of the flux concentrator act as the entry and exit ports for the sensor. The field to be measured has a very small flux density at the boundary at either end of the concentrator. The conservation of magnetic flux leads to a high flux density at the center of the flux concentrator where the transducer is located and the cross-sectional area (as seen by the flux) is orders of magnitude smaller than the input path. The magnetic induction Bᵢₙ=φ/Aᵢₙ at the end of the flux concentrator is significantly smaller than the magnetic induction B_{c}=φ/A_{c} at the center of the flux concentrator, where Aᵢₙ is the cross-sectional area of the end of the flux concentrator, and A_{c} is the cross-sectional area of the center of the flux concentrator. The flux concentrator has a hard axis of magnetization in the X direction and a soft (or easy) axis of magnetization in the Y direction. The high-permeability flux concentrator is designed to concentrate incoming flux at the transducer (i.e., the center of bow tie structure flux concentrator in FIG. 1).

FIG. 2 is a cross-sectional view of the sensor of FIG. 1 taken along line 2-2. In FIG. 2, the quiescent direction of magnetization of the flux concentrator, as illustrated by arrow 30, is oriented in the Y direction, and is substantially orthogonal to the direction of an applied magnetic field Hₑₓₜ. The orthogonal orientation of the quiescent magnetization can be used to produce a relatively large change in magnetization with the applied field. However, the orthogonal orientation of the quiescent magnetization is not required.

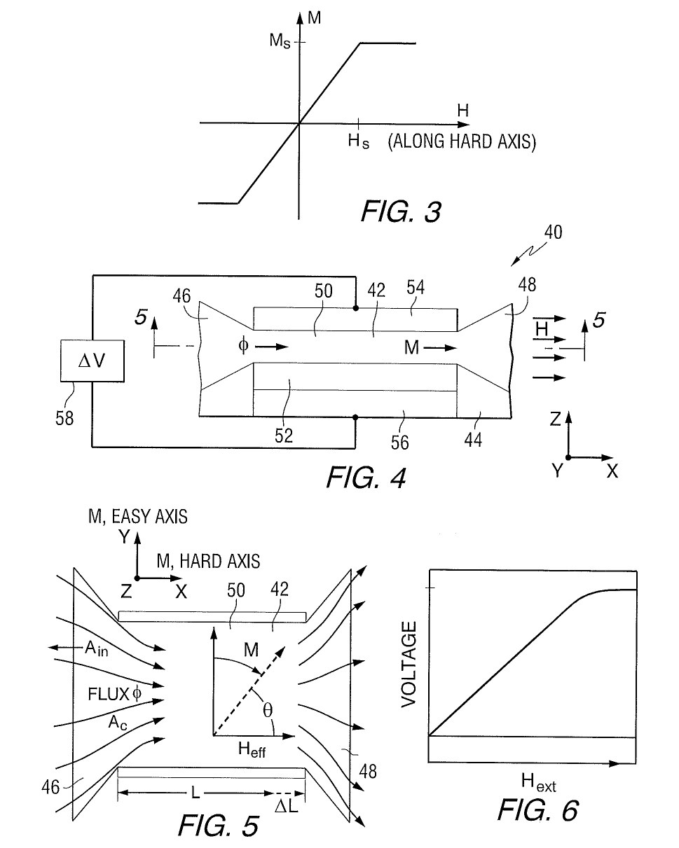

The response of the sensor to small magnetic fields is based on the anisotropic magnetic properties of the flux concentrator. FIG. 3 is a schematic depiction of the magnetization curve as a function of an applied field along the hard axis of magnetization, such as the hard axis direction depicted in FIG. 2, as a function of an applied field along the hard axis of magnetization for a uni-axial anisotropic magnetic material. The saturation magnetization is represented by Mₛ.

The magnetization responds to an arbitrarily small field, increasing linearly with the applied field until it is saturated along the hard axis (i.e., where M=Mₛ). Of course, very small fields produce a very small change in the magnetization, but the purpose of the flux concentrator is to amplify the magnetic response at the transducer enabling the detection of very small magnetic fields. The M-H loop in FIG. 3 represents the typical hard axis response of the magnetization to an external field for a standard geometry, such as a rectangle. The geometric structures used for the flux concentrator are unique, and the actual response curve has not yet been simulated or demonstrated experimentally. Since a linear response is generally desired for device operation, linearity would likely be one of the design guides in the device optimization process, both through modeling and experiments.

In previously known devices, room-temperature field sensitivity on the order of 10⁻¹¹ Tesla/√Hz (at 1 Hz) has been demonstrated with magnetostrictively coupled multiferroics at room temperature. However, it is possible to achieve some four orders of magnitude better signal with the integration of a high-efficiency flux concentrator. FIGS. 4 and 5 show a sensor that uses a multiferroic-based measurement technique.

FIG. 4 is a schematic side elevation view of a portion of a sensor 40 constructed in accordance with an embodiment of the invention. The sensor includes a flux concentrator 42 of ferromagnetic material supported by a substrate 44 or other support structure. The flux concentrator includes first, second and third portions 46, 48 and 50. The first and second portions (also referred to as end portions) of the flux concentrator have a larger cross-sectional area than the third portion (also referred to as the center portion). In the embodiment of FIG. 4, the flux concentrator has a bow tie shape.

When the sensor is exposed to a magnetic field H (e.g., applied in the X direction), magnetic flux φ passes through the flux concentrator, and induces a magnetization M change in the flux concentrator. Because the end portions have a larger cross-sectional area than the center portion, the change in magnetization orientation of the center portion is larger than that of the end portions.

A multiferroic or piezoelectric transducer 52 is connected to the third portion of the flux concentrator. The transducer produces an output signal in response to a physical change in the center portion resulting from the change in magnetization. For example, a piezoelectric transducer that is connected to the center portion can produce an output voltage in response to changes in the dimensions of the center portion caused by magnetostriction. Electrodes 54 and 56 are provided to connect the sensor to an external circuit 58, which in one example can measure a voltage between the electrodes. The multiferroic or piezoelectric material used in the embodiment of FIGS. 4 and 5, can be for example, Pb(ZrTi)O₃ [also referred to as PZT], Pb(MgNb)O₃—PbTiO₃ [also referred to as PMN—PT], or BiFeO₃.

FIG. 5 is a cross-sectional view of the sensor of FIG. 4 taken along line 5-5. In FIG. 5, the quiescent direction of magnetization of the flux concentrator is in the Y direction, and is substantially orthogonal to the direction of an applied magnetic field Hₑₓₜ. The orthogonal orientation of the quiescent magnetization can be used to produce a relatively large change in magnetization with the applied field. However, the orthogonal orientation of the quiescent magnetization is not required.

FIG. 6 is a graph of output voltage induced in ferroelectric layer and linear response to measured external field, Hₑₓₜ. The output voltage is:

$$Voltage ∝ \frac{Δ L}{L} ∝ \vert \vec{M} \times {\vec{H}}_{eff} \vert = {M}_{s} ( \frac{{A}_{in}}{{A}_{c}} ) {H}_{ext} sin θ .$$

FIG. 6 depicts the effect of magnetostriction in the flux concentrator as its magnetization orientation changes in response to the measured external field. The magnetostriction-induced structural change in the center portion of the flux concentrator generates a proportional change in the ferroelectric layer. This strains the piezoelectric layer with a consequent voltage drop that acts as the output voltage of the transducer. For example, a voltage can be induced across the thickness of the piezoelectric layer via transverse piezoelectric coupling. To the first order, the output signal is a linear function of the external magnetic field. Since the voltage is generated without any additional input power, this manifestation of the sensor operates passively.

As in the other embodiments, the output voltage is boosted by the gain of the flux concentrator. The capability of state-of-the-art multiferroic-heterostructure sensors is nearly 10⁻¹¹ Tesla/√Hz sensitivity (at 1 Hz) at room temperature, without the incorporation of any form of flux concentrator. The flux concentrator of FIGS. 4 and 5 is designed to be integrated as the ferromagnetic layer of just such a structure, where several more orders of magnitude of signal can be anticipated. As long as the noise sources introduced by the flux concentrator can be managed, then it is estimated that several orders of magnitude greater field sensitivity can be achieved.

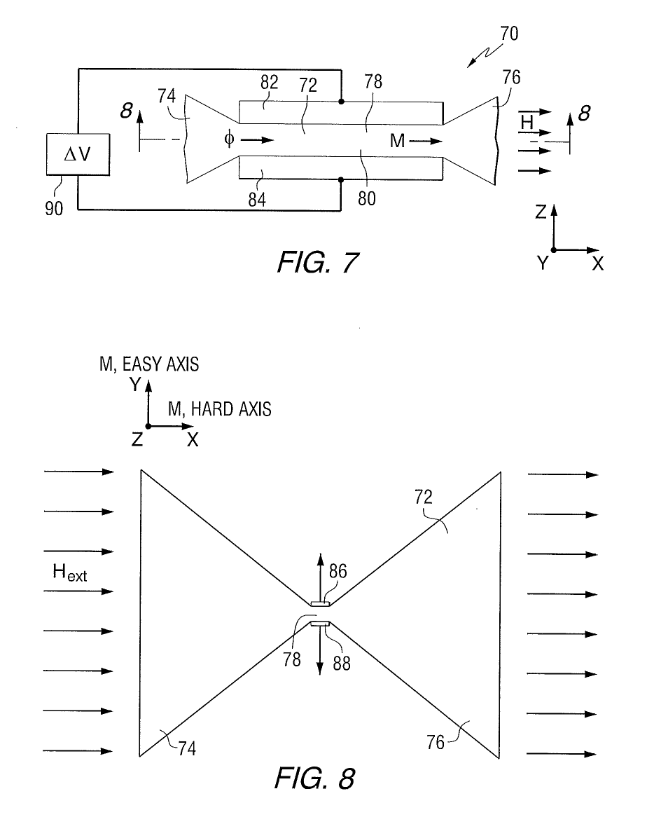

In another embodiment, the Extraordinary Hall Effect (EHE) in ferromagnetic materials can be used to produce an output voltage. In sensors that utilize the Extraordinary Hall Effect, only the single ferromagnetic layer of the bow tie flux concentrator is needed and the output voltage is induced in that layer. FIG. 7 is a cross-sectional view of an embodiment of a sensor 70 constructed in accordance with this aspect of the invention. FIG. 8 is a cross-sectional view of the sensor of FIG. 7 taken along line 8-8.

In the embodiment of FIGS. 7 and 8, a flux concentrator 72 of ferromagnetic magnetic material includes first, second and third portions 74, 76 and 78. The first and second portions (also referred to as end portions) of the flux concentrator have a larger cross-sectional area than the third portion (also referred to as the center portion). In the embodiment of FIG. 7, the flux concentrator has a bow tie shape.

When the sensor is exposed to a magnetic field H (e.g., applied in the X direction), magnetic flux φ passes through the flux concentrator, and induces a change in magnetization M in the flux concentrator. Because the end portions have a larger cross-sectional area than the center portion, the net magnetization of the center portion is larger than that of the end portions.

An Extraordinary Hall Effect transducer 80 is formed by the third portion of the flux concentrator. Electrodes 82, 84, 86 and 88 are provided to connect the sensor to an external circuit 90, which in one example can supply a current to the transducer, using for example electrodes 82 and 84, and can measure a voltage between electrodes 86 and 88. The material used for the flux concentrator of the embodiment of FIGS. 7 and 8, can be for example, alloys of NiFe, FePtB, NdFe, or HfFeCo.

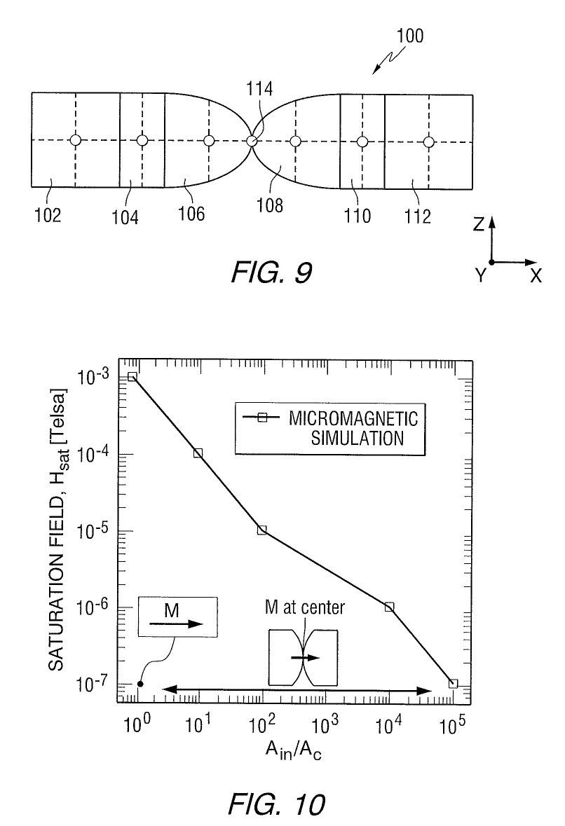

The performance of an example sensor has been modeled using the structure 100 illustrated in FIG. 9. The modeling process begins by creating a CAD drawing of the concentrator in the finite element mesh software, gmsh. The geometry of structure 100 is divided into modules 102, 104, 106, 108, 110 and 112 with a sphere (to represent a volume) at the center of each module. Each volume module can have independent material and mesh properties defined as inputs to the model. The center 114 of the structure is where the transducer is integrated. The output of the simulation provides the average magnetic state for each module, so the magnetization in a specific area of interest can be extracted, such as at the transducer, for example. The geometry shown in FIG. 9 is not necessarily an optimum design for a concentrator.

The structure 100 uses an elongated parabolic geometry to gradually concentrate the flux (via magnetization gradient) to a center point where the transducer is ultimately integrated. The flux concentrator is symmetric about the transducer point so a large magnetization rotation can be induced at this center point without generating magnetic surface charge, which would counter the magnetization rotation in an effort to minimize the free energy.

As mentioned earlier, only the ferromagnetic element of the transducer is part of the concentrator. As a reference, with no external field, the magnetization is intended to be along the Y axis (vertical), which can be readily achieved by inducing magnetic anisotropy along the Y direction (i.e., Hₖ∥Y). This concentrator is sensitive to the external magnetic field component along the X axis (horizontal).

The entire structure is continuous, so the parabolas are continuous with the center. The ferromagnetic transducer element has a 10:1:1 aspect ratio. The aspect ratio creates a stabilizing shape anisotropy (of the magnetization) along the Y-axis, while also promoting an efficient response to external fields.

The modeling results are intended as a proof of concept, and are by no means complete. Thus, in this proof of concept rather general material properties are assumed to be comparable to a range of soft magnetic materials, with the following material parameters: saturation magnetization 4πM_{S}=1.0 T, exchange constant A=10⁻¹¹ J/m, magnetocrystalline anisotropy of K=40 J/m³ (Hₖ=1 Oe) along the Y-axis. A damping constant α=1.0, was assumed in order to speed up the convergence of our simulations. For the proof of concept, the magnetoelastic energy was not included, so Eₑₓₜ, Eₘₛ, Eₐₙᵢ and E_{exch} are the only contributions to the total energy.

The simulations were run using the finite element micromagnetics package. Starting with a homogeneous saturation magnetization in the Y direction, the structured ferromagnet (the flux concentrator) was allowed to relax in an external field (or zero field), solving for the equilibrium energies.

FIG. 10 is a graph of micromagnetic simulation results on the high-efficiency flux concentrator: Hₛₐₜ vs Aᵢₙ/A_{c}, the magnetic field required to align the magnetization (at the transducer) parallel to the field direction versus the aspect ratio of the input area (Aᵢₙ) to the cross-sectional area at the transducer (A_{c}). The simulation (magnetization) and geometry for Aᵢₙ/A_{c}=1, as well as Aᵢₙ/A_{c}>1, are shown as insets for clarity.

FIG. 10 summarizes results from the micromagnetic simulations on the flux concentrator of FIG. 9. The graph is a plot of the saturation magnetic field versus the ratio of the cross-sectional areas at the input (Aᵢₙ) and center (A_{c}) of the concentrator, Hₛₐₜ vs Aᵢₙ/A_{c}. All material parameters (anisotropy, exchange, saturation magnetization, etc.) are the same for each simulation (each data point), so the results merely reflect the design differences captured by the aspect ratio, Aᵢₙ/A_{c}. The saturation field is that required to align the magnetization (at the transducer) parallel to the field direction. The case of Aᵢₙ/A_{c}=1 corresponds to a rectangular geometry (or cuboid in 3D) where there is no narrowing between the ends (or inputs) and the center of the structure (see inset). In other words, the concentrator is just a ferromagnetic bar, and the saturation field is essentially the bulk saturation field for the given structure size (cm-scale in X and Y, with a thickness of 1 micron). The data demonstrates the geometrical effect of concentrating magnetic flux in the form of the magnetization. Over the range in geometry (Aᵢₙ/A_{c}) thus far considered, the simulations reveal a four-orders-of-magnitude increase in the magnetic response at the transducer within the self-imposed design constraints (Aᵢₙ/A_{c}˜10⁵). The graph indicates some variation in the slope in “gain”. It is not yet clear if that is due to fundamental asymptotic behavior, or if it can be overcome with further design changes, but there is still considerable parameter space to explore for further optimizing the effect. With that in mind, the sensitivity of our modeled device is remarkable, ultimately being saturated by a 100-nTesla magnetic field, and it is packaged on a practical size scale (1 cm input width, for example). Overall, this is a strong validation of the device concept, while there is still considerable optimization that can be pursued in the modeling that will mimic process development that can be carried out on real devices.

The results of FIG. 10 are in reasonably good agreement with the simplified derivation for the magnetic gain discussed earlier. The data also demonstrates the revolutionary potential of the high-efficiency flux concentrator.

In another aspect, the invention addresses noise sources and mitigation techniques. Noise limitations in the detection of minute magnetic fields are typically 1/f dominated. There are a couple of reasons for this, one from the field source and one from the sensors. Many field measurements of interest are at low frequencies, while most detector noise has intrinsic 1/f-like behavior. Familiar noise sources for the type of structures described above are thermal, electronic, magnetic, and the convolution of all three.

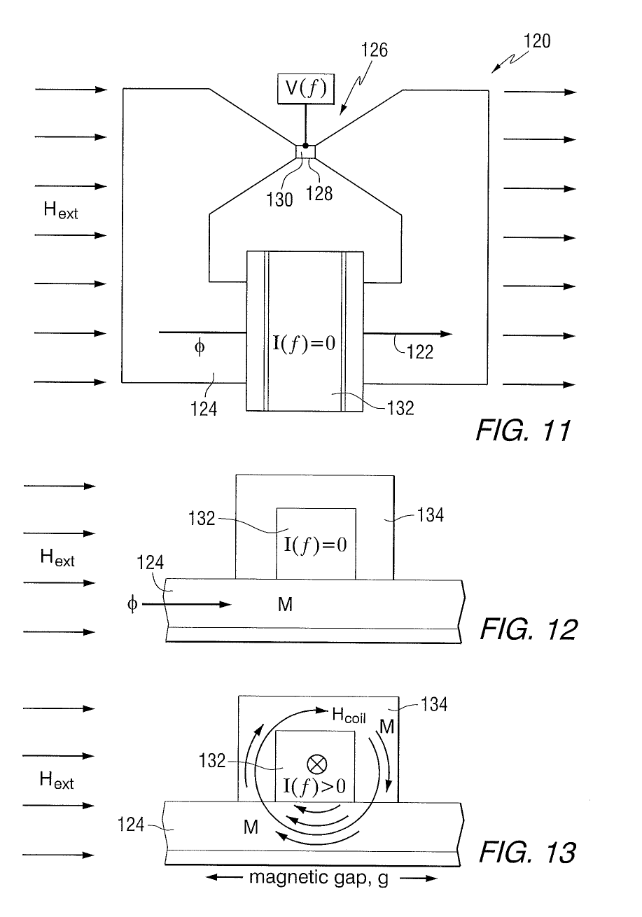

FIG. 11 is a top-down schematic view of sensor 120 with a parallel flux path and integrated coil. The bottom leg of the magnetic circuit provides a parallel flux path that can be designed to act as a short circuit to magnetic flux in the quiescent state (current off), diverting the flux away from the concentrator.

The sensor of FIG. 11 incorporates a flux path 122 with a tunable magnetic reluctance path (i.e., the bottom leg 124 of the structure) in parallel with the flux concentrator 126. The bottom leg has a relatively large cross-sectional area which acts like a short circuit for magnetic flux. The constricted area 128 of the concentrator has a substantially larger reluctance, so most of the flux will “flow” through the low-reluctance path. In this case, there is minimal signal at the transducer 130, as the flux has essentially been “chopped” off. As can be seen in both FIGS. 12 and 13, there is a coil 132 integrated with the bottom leg. The coil produces a current-induced magnetic field capable of saturating the underlying magnetic material.

The coil can be cladded with a soft magnetic material 134 to confine the magnetic field locally. When a current is applied to the coil, the magnetization in that leg is saturated over a length comparable to the dimensions of the coil, as depicted in FIG. 13. The magnetic “gap” then creates a very large reluctance, redirecting the flux to flow through the concentrator. Then the reluctance is orders of magnitude larger due to the gap, and the flux will be largely diverted back to the concentrator. Thus, the modulation of the coil current modulates the flux at the transducer, effectively shifting its operating frequency out, and further reducing the noise floor as a result.

FIG. 12 is a cross-section of magnetic short-circuit in the quiescent state (I=0). FIG. 13 is a cross-section showing that the field from current-carrying coil, H_{coil}, locally saturates magnetization in the low-reluctance leg of the magnetic circuit, effectively cutting off the flux path.

As an illustrative example, for a coil current of frequency 10 kHz, the transducer will see a modulated signal (from an external field) at that frequency, shifting the operating frequency of the sensor to no less than 10 kHz. To avoid pickup of the coil field by the sensor, the coil would be cladded with a high-permeability ferromagnetic material to contain the drive field and effectively shield the sensor. Saturation of the cladding by the drive field can be avoided by making it thick compared to the bottom leg of the magnetic sensor circuit, or by some comparable design. Cladded coils are used in MRAM and other magneto-electronic devices where cross talk and pickup need to be minimized. Additionally, the drive coil and parallel leg are not constrained to be in close proximity to the sensor, so pickup can also be minimized by maximizing the physical separation between the top (sensor) and bottom (modulator) legs of the magnetic circuit.

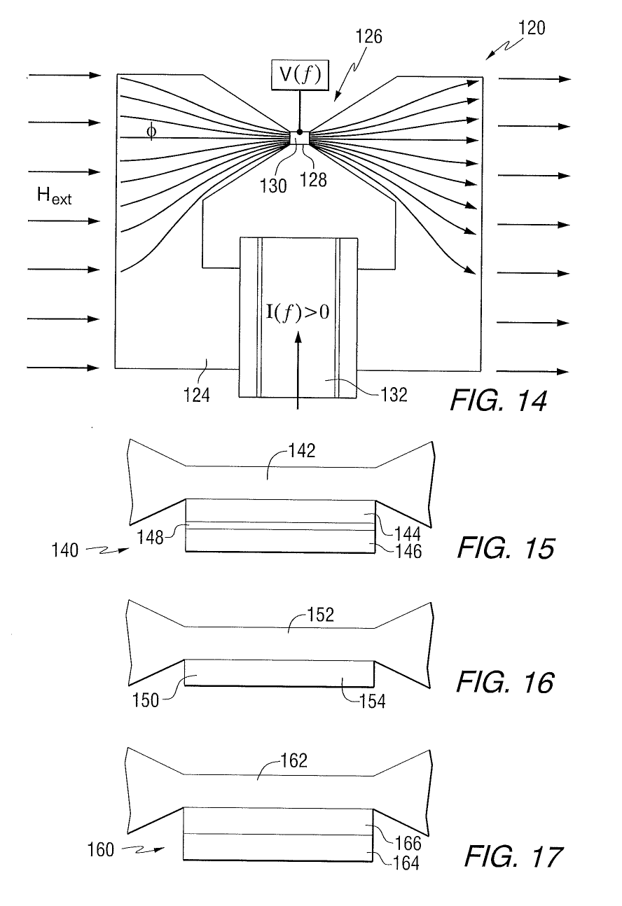

FIG. 14 is a top-down-view wherein the field from current-carrying coil, H_{coil}, locally saturates magnetization in the low-reluctance leg of the magnetic circuit, effectively cutting off this flux path and diverting the flux back to the concentrator.

FIG. 15 is a schematic representation of a GMR or TMR transducer 140 in combination with a flux concentrator 142. The transducer includes a magnetic free layer 144 and a magnetic fixed layer 146. A non-magnetic spacer layer 148 is positioned between the free layer and the fixed layer. The direction of magnetization of the fixed layer does not change in response to a magnetic field detected by the sensor. The free layer is exchange coupled with the flux concentrator such that the directions of magnetization of the flux concentrator and the free layer move together. Electrodes can be provided for connection to an external circuit that can supply bias current to the transducer and can measure a voltage across the transducer. If the flux concentrator has a bow tie shape, the transducer can be positioned adjacent to the center portion of the flux concentrator. With this arrangement, the flux concentrator material and the free layer can be optimized independently but will have magnetizations that act in unison.

FIG. 16 is a schematic representation of an Extraordinary Hall Effect transducer 150 in combination with a flux concentrator 152. The transducer includes a magnetic free layer 154 made of an Extraordinary Hall Effect material. The free layer is exchange coupled with the flux concentrator such that the directions of magnetization of the flux concentrator and the free layer move together. Electrodes can be provided for connection to an external circuit that can supply bias current to the transducer and can measure a voltage across the transducer. If the flux concentrator has a bow tie shape, the transducer can be positioned adjacent to the center portion of the flux concentrator.

FIG. 17 is a schematic representation of a multiferroic transducer 160 in combination with a flux concentrator 162. The transducer includes a piezoelectric layer 164 and a magnetostrictive free layer 166 between the piezoelectric layer 164 and the flux concentrator. The free layer is exchange coupled with the flux concentrator such that the directions of magnetization of the flux concentrator and the free layer move together. Changes in the magnetization of the magnetostrictive free layer cause changes in the dimensions of the magnetostrictive free layer. This creates strain in the piezoelectric layer that results in a voltage across the piezoelectric layer. Electrodes can be provided for connection to an external circuit that can measure the voltage across the transducer. If the flux concentrator has a bow tie shape, the transducer can be positioned adjacent to the center portion of the flux concentrator.

In the various embodiments, the high-efficiency flux concentrator (e.g., the high-permeability ferromagnetic bow tie structure), enables field sensitivity that is potentially orders of magnitude beyond present technology. A distinction of this concept from previously known flux concentration techniques is that the magnetic field to be detected couples directly to the ferromagnetic layer of the transducer, where magnetization is effectively amplified and the output signal is derived from the transducer. By geometrically increasing the flux density (but not magnetic field, H) in the magnetic layer, ΔM is amplified from the input of the concentrator to a maximum value at the transducer, where the magnetization gain=ΔMₛₑₙₛₒᵣ/ΔMᵢₙₚᵤₜ can be designed to be many orders of magnitude.

The various embodiments virtually eliminate the issue of demagnetization fields in the flux concentrator, and directly induce a magnetization change, ΔM, at the transducer which can be orders of magnitude larger than with previously existing techniques. The magnetization of the center portion of the flux concentrator can be converted to an electrical output using a variety of known magneto-electric effects such as giant magnetoresistance (GMR), tunneling magnetoresistance (TMR), the Extraordinary Hall Effect (EHE) in ferromagnetic materials, and multiferroic coupling, among others. In this way, magnetization changes in the flux concentrator can induce measurable voltages, which act as the output signal of the magnetic field sensor.

The minute field to be measured is the low flux density input at the (large volume) ends of the bow tie structure and is concentrated to a high flux density at the center of the bow tie where the volume is constricted. The center of the bow tie structure can act as the active region of the transducer where an appropriate electronic output signal is produced. The high flux density at the center of the bow tie manifests itself as a measurable change in the magnetization orientation, as opposed to the induced magnetic field used with previously known flux concentrators. Since the ferromagnetic layer is continuous from one end of the bow tie to the other, demagnetization fields are (intentionally) minimized, enabling a much greater response at the transducer. This device enables orders of magnitude more sensitivity to minute magnetic fields than previously known flux concentrators.

The techniques described above outline design concepts for mitigating magnetic and electrical sources of noise. The fabrication of the materials also plays a key role in rejecting noise sources. One of the biggest concerns is with the flux concentrator because it has the largest physical scale and is responsible for transforming minute magnetic fields to a large magnetic change, i.e., it is a high gain element with the potential of also amplifying magnetic noise. Ferromagnetic materials with poor domain formation can exacerbate magnetic noise, for example. Therefore, it is desirable to create the flux concentrator with a well-defined anisotropy and excellent uniformity, for example. However, within the hard disk drive industry, processes have been exhaustively developed to do just this sort of thing, as high-permeability magnetic shields and yokes of 100-micron length scales are fabricated (using sputtering and/or plating deposition methods) and physically coupled with much smaller scale magnetic transducers (<100 nm) having state-of-the-art magnetic sensitivity. Similarly, high quality magnetic materials can be fabricated as part of the flux concentrator.

While the invention has been described in terms of several examples, it will be apparent to those skilled in the art that various changes can be made to the disclosed examples without departing from the scope of the invention as defined by the following claims. The implementations described above and other implementations are within the scope of the claims.

What is claimed is:

1. A magnetic sensor comprising:
a flux concentrator; and
a transducer producing an output responsive to a change in magnetization in the flux concentrator.

2. The magnetic sensor of claim 1, wherein the flux concentrator comprises;
first, second and third portions, wherein the third portion is between the first and second portions and the cross-sectional area of the third portion is smaller than the cross-sectional area of the first and second portions; and
the transducer produces an output responsive to a change in magnetization in the third portion of the flux concentrator.

3. The magnetic sensor of claim 1, wherein the flux concentrator is symmetrical on opposite sides of the third portion.

4. The magnetic sensor of claim 1, wherein the flux concentrator has a hard magnetization axis in a direction from the first portion to the second portion and easy magnetization substantially perpendicular to the hard magnetization axis and parallel to a plane of the magnetic layer.

5. The magnetic sensor of claim 1, further comprising:
a flux path magnetically coupled in parallel with the flux concentrator; and
a coil adjacent to the flux path.

6. The magnetic sensor of claim 5, further comprising:
a magnetic material around the coil.

7. The magnetic sensor of claim 1, wherein the transducer comprises one of:
a piezoelectric transducer;
a magnetoresistive transducer;
a multiferroic transducer;
a tunneling magnetoresistance transducer;
a ferromagnetic Extraordinary Hall Effect transducer; or
a ferroelectric transducer.

8. The magnetic sensor of claim 1, wherein the transducer comprises:
a free layer, wherein the flux concentrator is exchange coupled with the free layer.

9. The magnetic sensor of claim 8, further comprising:
a fixed layer; and
a spacer layer between the fixed layer and the free layer.

10. The magnetic sensor of claim 1, wherein the transducer comprises:
a ferromagnetic Extraordinary Hall Effect free layer, wherein the flux concentrator is exchange coupled with the free layer.

11. The magnetic sensor of claim 1, wherein the transducer comprises:
a magnetostrictive free layer, wherein the flux concentrator is exchange coupled with the magnetostrictive free layer; and
a piezoelectric layer connected to the free layer.

12. The magnetic sensor of claim 11, wherein the magnetostrictive free layer comprises one of:
Tb₁₋ₓDy_{yx}Fe_{2-y} or Fe₁₋ₓGaₓ.

13. The magnetic sensor of claim 1, further comprising:
a circuit for measuring a voltage across the transducer.

14. The magnetic sensor of claim 13, wherein the circuit supplies a bias current to the transducer.

15. The magnetic sensor of claim 1, wherein the flux concentrator comprises an alloy of one of:
NiFe, NdFe, CoFe, FePtB, HfFeCo, Tb₁₋ₓDy_{yx}Fe_{2-y} or Fe₁₋ₓGaₓ.

16. The magnetic sensor of claim 1, wherein the transducer comprises one of:
Pb(ZrTi)O₃ or Pb(MgNb)O₃—Pb—TiO₃.

17. A magnetic sensor comprising:
a flux concentrator having first and second portions and a third portion between the first and second portions, wherein the cross-sectional area of the third portion is smaller than the cross-sectional area of the first and second portions; and
wherein the third portion of the flux concentrator includes an Extraordinary Hall Effect material.

18. The magnetic sensor of claim 17, further comprising:
a circuit for supplying a bias current to the transducer and for measuring a voltage across the transducer.

19. The magnetic sensor of claim 17, wherein the Extraordinary Hall Effect material comprises an alloy of one of:
NdFe, CoFe, FePtB, or HfFeCo.
